(19) United States
(12) Patent Application Publication
(10) Pub. No.: US 2023/0377847 A1
(43) Pub. Date: Nov. 23, 2023

(54) SPOT TYPE ATMOSPHERIC PRESSURE PLASMA DEVICE

(71) Applicant: CREATING NANO TECHNOLOGIES, INC., TAINAN CITY (TW)

(72) Inventors: Yi-Ming HSU, Tainan City (TW); Liang-Chun WANG, Tainan City (TW); Yung-Hao CHEN, Tainan City (TW); Po-Hsuan CHEN, Tainan City (TW); Wen-Chieh TAN, Tainan City (TW); Huang-Wei CHEN, Tainan City (TW)

(21) Appl. No.: 17/664,224

(22) Filed: May 20, 2022

(51) Int. Cl. H01J 37/32

(52) U.S. Cl. CPC H01J 37/3244; H01J 37/32825; H01J 37/32513; H01J 37/3255; H01J 2237/335; H01J 2237/334

(57) ABSTRACT

A spot type atmospheric pressure plasma device includes a metal casing, a metal electrode, a dielectric layer, and a gas channel. The metal electrode is disposed in an inner space of the metal casing. The dielectric layer is disposed in the inner space and surrounds an outer side surface of the metal electrode. A central area of a bottom of the dielectric layer has a plasma jet, and a bottom of the metal electrode is adjacent to the plasma jet. The gas channel includes a first section, a second section, and a third section. The first section passes through the metal casing and the dielectric layer. The second section is connected to the first section and extends between the dielectric layer and the outer side surface. The third section is connected to the second section, and is configured to direct a working gas to the plasma jet.

### BACKGROUND

### Field of Invention

The present disclosure relates to a plasma technique, and more particularly to a spot type atmospheric pressure plasma device.

### Description of Related Art

Atmospheric plasma is the plasma generated at or near atmospheric pressure. An atmospheric plasma system has no vacuum apparatus and can continuously process workpieces, so compared with a vacuum plasma system, the atmospheric plasma system has advantages in apparatus and process cost.

According to the different forms of plasma, the atmospheric plasma can be roughly divided into corona discharge, dielectric barrier discharge (DBD), plasma jet, and plasma torch, etc. The dielectric barrier discharge technology has attracted attention because the discharge gas temperature is close to a room temperature, which can avoid wasting energy on raising the gas temperature. However, the plasma density generated by the dielectric barrier discharge technology is low, and the plasma removal efficiency is poor.

### SUMMARY

Therefore, one objective of the present disclosure is to provide a spot type atmospheric pressure plasma device, and a gas flow channel of which can directly guide a working gas to a plasma jet in a central area of a bottom of a dielectric layer. Accordingly, most of the working gas can be dissociated to form plasma near the plasma jet. Therefore, the formation of plasma in an inner space of a metal casing can be greatly reduced, which can not only avoid unnecessary waste of power, but also make the plasma more concentrated and closer to a workpiece to be processed, thereby enhancing a plasma treatment effect.

Another objective of the present disclosure is to provide a spot type atmospheric pressure plasma device, in which an outlet section of the gas flow channel may penetrate in a metal electrode, such that it can prevent plasma from being formed in the outlet section of the gas flow channel, further reduce unnecessary waste of power, and make the plasma more concentrated. Therefore, the plasma treatment can be more focused, thereby preventing a non-treatment area from being damaged.

Still another objective of the present disclosure is to provide a spot type atmospheric pressure plasma device, which may use a sealing ring to surround an outer side surface of the dielectric layer to seal a chamber of the metal casing, such that it can more effectively prevent plasma from being formed in the chamber.

Yet another objective of the present disclosure is to provide a spot type atmospheric pressure plasma device, in which the outlet section of the gas channel includes a reduction portion of a smaller radial dimension adjacent to the outlet. The gas can be compressed firstly in the reducing portion and then expanded at the outlet, such that the pressure at the outlet can be slightly lower than the atmospheric pressure, which is beneficial to the discharging to dissociate the working gas into plasma.

Further another objective of the present disclosure is to provide a spot type atmospheric pressure plasma device, in which the metal casing may include an air curtain device, and an air curtain may be formed on the periphery of the plasma jet to further limit the scope of the plasma, such that it can more effectively prevent the plasma from damaging the non-treatment area.

According to the aforementioned objectives, the present disclosure provides a spot type atmospheric pressure plasma device. The spot type atmospheric pressure plasma device includes a metal casing, a metal electrode, a dielectric layer, and a gas channel. The metal casing has an inner space. The metal electrode is disposed in the inner space. The dielectric layer is disposed in the inner space and surrounds an outer side surface of the metal electrode. A central area of a bottom of the dielectric layer has a plasma jet, and a bottom of the metal electrode is adjacent to the plasma jet. The gas channel includes a first section, a second section, and a third section. The first section passes through the metal casing and the dielectric layer. The second section is connected to the first section and extends between the dielectric layer and the outer side surface of the metal electrode. The third section is connected to the second section, and is configured to direct a working gas to the plasma jet.

According to one embodiment of the present disclosure, the third section penetrates into the metal electrode from the outer side surface of the metal electrode, and extends from an interior of the metal electrode to the bottom of the metal electrode.

According to one embodiment of the present disclosure, the third section includes a transverse portion and a longitudinal portion. The transverse portion laterally passes through the metal electrode. The longitudinal portion longitudinally extends from the transverse portion to the bottom of the metal electrode.

According to one embodiment of the present disclosure, the spot type atmospheric pressure plasma device further includes a sealing ring, in which the metal electrode further includes a groove disposed in the outer side surface of the metal electrode, the groove is located below the transverse portion, and the sealing ring is disposed in the groove and abuts against the dielectric layer.

According to one embodiment of the present disclosure, the third section includes a first portion, a second portion, and a third portion connected in sequence, an outlet of the gas channel is located in the third portion, and a radial dimension of the second portion is smaller than a radial dimension of the first portion and a radial dimension of the third portion.

According to one embodiment of the present disclosure, the second section includes several spiral grooves spirally arranged in the outer side surface of the metal electrode to guide the working gas to the third section along the outer side surface of the metal electrode.

According to one embodiment of the present disclosure, the metal electrode includes a first portion and a second portion connected to each other, the second section is located between the first portion and the dielectric layer, and the third section is located between the second portion and the dielectric layer, and wherein a radial dimension of the first portion is greater than a radial dimension of the second portion.

According to one embodiment of the present disclosure, the metal electrode further includes a third portion connected to the first portion, wherein a radial dimension of the third portion is smaller than the radial dimension of the first portion.

According to one embodiment of the present disclosure, the metal casing further includes an air curtain device, and the air curtain device is adjacent to the plasma jet and is configured to form an air curtain around the plasma jet.

According to one embodiment of the present disclosure, the air curtain device is an air extraction device or an air intake device.

### BRIEF DESCRIPTION OF THE DRAWINGS

The disclosure can be more fully understood by reading the following detailed description of the embodiment, with reference made to the accompanying drawings as follows:

FIG. 1 is a schematic cross-sectional view of a spot type atmospheric pressure plasma device in accordance with one embodiment of the present disclosure;

FIG. 2A is a schematic cross-sectional view of a metal electrode of a spot type atmospheric pressure plasma device in accordance with one embodiment of the present disclosure;

FIG. 2B is a schematic cross-sectional view of another metal electrode of a spot type atmospheric pressure plasma device in accordance with one embodiment of the present disclosure;

FIG. 3 is a schematic cross-sectional view of a spot type atmospheric pressure plasma device in accordance with another embodiment of the present disclosure; and

FIG. 4 is a schematic side view of a metal electrode of a spot type atmospheric pressure plasma device in accordance with another embodiment of the present disclosure.

### DETAILED DESCRIPTION

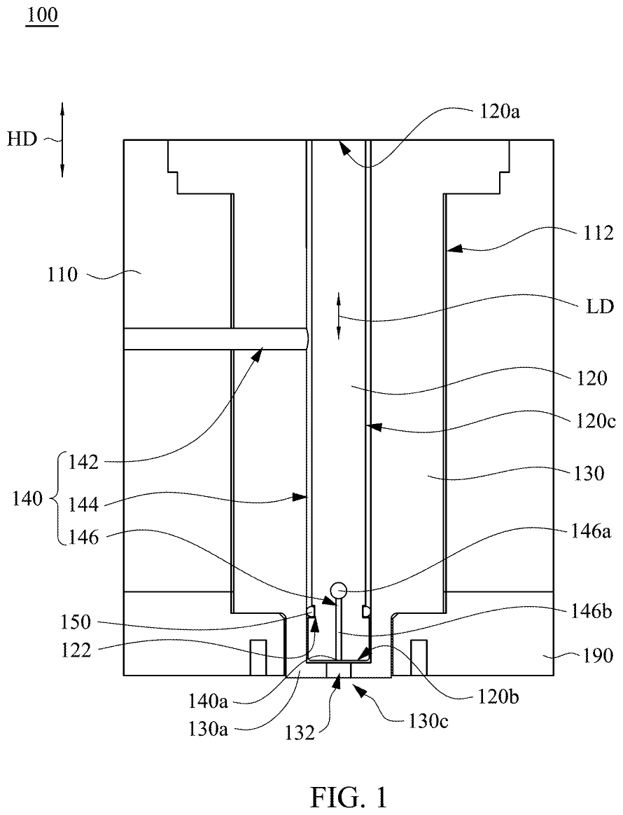

Referring to FIG. 1, FIG. 1 is a schematic cross-sectional view of a spot type atmospheric pressure plasma device in accordance with one embodiment of the present disclosure. A spot type atmospheric pressure plasma device 100 may be a dielectric barrier discharge plasma device. The plasma of the spot type atmospheric pressure plasma device 100 is relatively concentrated, such that the spot type atmospheric pressure plasma device 100 is suitable for cleaning and etching of workpieces. The spot type atmospheric pressure plasma device 100 may mainly include a metal casing 110, a metal electrode 120, a dielectric layer 130, and a gas channel 140.

The shape of the metal casing 110 can be designed according to the requirements of the process or the environment. For example, the metal casing 110 may be a rectangular, square, or cylindrical hollow casing. As shown in FIG. 1, the metal casing 110 includes an inner space 112. The inner space 112 can accommodate the metal electrode 120 and the dielectric layer 130. In addition, the main portion of the gas channel 140 is located in the inner space 112.

The metal electrode 120 may be a long columnar structure. For example, the metal electrode 120 may be a cylindrical-like structure. The metal electrode 120 is disposed within the inner space 112 of the metal casing 110. In some examples, the metal electrode 120 may be disposed along a height direction HD of the metal casing 110, i.e. a length direction LD of the metal electrode 120 is substantially parallel to the height direction HD of the metal casing 110. The metal electrode 120 has a top 120a and a bottom 120b, which are opposite to each other, and an outer side surface 120c connected between the top 120a and the bottom 120b. The top 120a of the metal electrode 120 is connected to the metal casing 110. A material of the metal electrode 120 may be any suitable metal, such as stainless steel, aluminum, and platinum.

The dielectric layer 130 is also disposed within the inner space 112 of the metal casing 110 and surrounds the outer side surface 120c of the metal electrode 120. Therefore, the dielectric layer 130 may be a hollow columnar structure, and the metal electrode 120 is inserted in the dielectric layer 130. The dielectric layer has a bottom 130a. In the present embodiment, as shown in FIG. 1, a central region 130c of the bottom 130a of the dielectric layer 130 is provided with a plasma jet 132, and the bottom 120b of the metal electrode 120 is adjacent to the plasma jet 132. In the present embodiment, the dielectric layer 130 also wraps an outer periphery of the bottom 120b of the metal electrode 120. That is, the bottom 130a of the dielectric layer 130 extends below the outer periphery of the bottom 120b of the metal electrode 120, such that the metal electrode 120 is located above the bottom 130a of the dielectric layer 130. In the example in which the metal electrode 120 is a cylindrical-like structure, the dielectric layer 130 may be a circular tube structure, such as a quartz circular tube.

The gas channel 140 can guide the working gas from the outside of the spot type atmospheric pressure plasma device 100 to the plasma jet 132 of the dielectric layer 130 through the metal casing 110, the dielectric layer 130, and the metal electrode 120. In some examples, as shown in FIG. 1, the gas channel 140 includes a first section 142, a second section 144, and a third section 146. The first section 142 may, for example, laterally pass through the metal casing 110 and the dielectric layer 130 from an outer side surface of the metal casing 110. The second section 144 is connected to the first section 142 and is in fluid communication with the first section 142. The second section 144 may extend longitudinally downward from the first section 142 between the dielectric layer 130 and the outer side surface 120c of the metal electrode 120. The third section 146 is connected to the second section 144 and is in fluid communication with the second section 144. That is, the first section 142, the second section 144, and the third section 146 are connected to each other in sequence. An outlet 140a of the gas channel 140 is located at an end of the third section 146. The third section 146 is located above the plasma jet 132, and can guide the working gas in the gas channel 140 to the plasma jet 132.

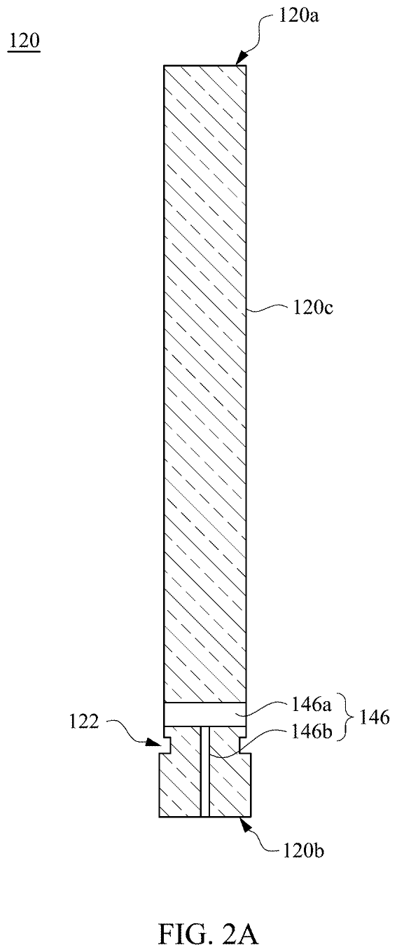

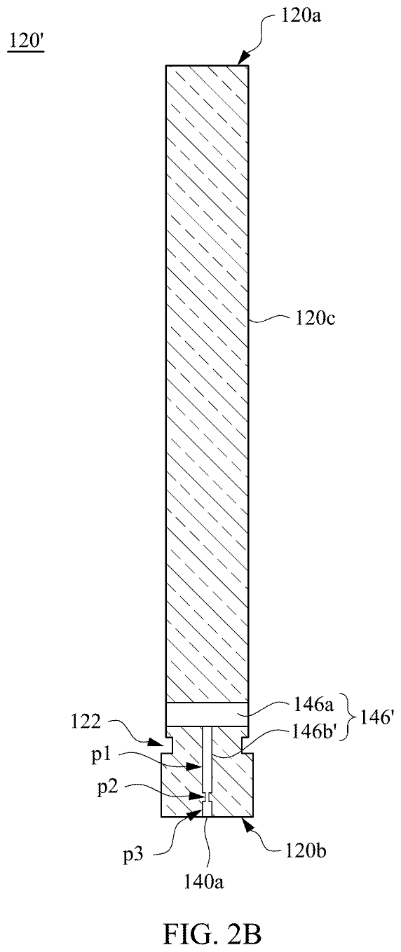

Referring to FIG. 1 and FIG. 2A simultaneously, FIG. 2A is a schematic cross-sectional view of a metal electrode of a spot type atmospheric pressure plasma device in accordance with one embodiment of the present disclosure. In the present embodiment, the third section 146 of the gas channel 140 penetrates into the metal electrode 120 from the outer side surface 120c of the metal electrode 120 and further extends longitudinally downward from an interior of the metal electrode 120 to the bottom 120b of the metal electrode 120. In some examples, as shown in FIG. 2A, the third section 146 includes a transverse portion 146a and a longitudinal portion 146b. The transverse portion 146a may laterally pass through the metal electrode 120 from the outer side surface 120c of the metal electrode 120. A top of the longitudinal portion 146b may be connected to the transverse portion 146a, and may longitudinally extend downward from the transverse portion 146a to the bottom 120b of the metal electrode 120. For example, the longitudinal portion 146b may be, for example, connected to a middle region of the transverse portion 146a, such that a cross-sectional shape of the longitudinal portion 146b and the transverse portion 146a is in a T-like shape.

In some examples, as shown in FIG. 1 and FIG. 2A, the spot type atmospheric pressure plasma device 100 further includes a sealing ring 150. In addition, the metal electrode 120 further includes a groove 122. The groove 122 is recessed in the outer side surface 120c of the metal electrode 120, and the groove 122 is located below the transverse portion 146a. The sealing ring 150 is disposed in the groove 122 and abuts against the dielectric layer 130. That is, the sealing ring 150 is arranged around the outer side surface 120c of the metal electrode 120 and sandwiched between the metal electrode 120 and the dielectric layer 130. Therefore, the sealing ring 150 can seal one end of the second section 144 to prevent the working gas from flowing out of this end of the second section 144. Accordingly, the working gas in the second section 144 can be forced to flow toward the transverse portion 146a of the third section 146 above the sealing ring 150, such that the working gas can be further guided by the longitudinal portion 146b to flow to the plasma jet 132 below the longitudinal portion 146b.

Through the gas channel 140, the working gas can be directly guided to the bottom 120b of the metal electrode 120 adjacent to the plasma jet 132, such that the working gas can be concentrated near the plasma jet 132 and then be discharged and dissociated into plasma. Therefore, the plasma can be more focused, the plasma is closer to the workpiece to be processed, and the plasma energy can be confined to a smaller area, thereby etching the material of the workpiece or removing contaminants from workpiece accurately and efficiently.

Referring to FIG. 2B, FIG. 2B is a schematic cross-sectional view of another metal electrode of a spot type atmospheric pressure plasma device in accordance with one embodiment of the present disclosure. A structure of the metal electrode 120′ is substantially the same as that of the aforementioned metal electrode 120. A difference between the metal electrodes 120′ and 120 is that a third section 146′ of the gas channel within the metal electrode 120′ is different from the third section 146 of the metal electrode 120.

A longitudinal portion 146b′ of the third section 146′ includes a first portion p1, a second portion p2, and a third portion p3 connected to each other in sequence. Specifically, the second portion p2 is located between the first portion p1 and the third portion p3, and two opposite ends of the second portion p2 are respectively connected to the first portion p1 and the portion part p3. An outlet 140a is located in the third portion p3. A radial dimension of the second portion p2 is smaller than a radial dimension of the first portion p1 and also smaller than a radial dimension of the third portion p3.

When the working gas flows from the first portion p1 into the second portion p2, the working gas is compressed due to the smaller radial dimension of the second portion p2. When the working gas then flows into the third portion p3 from the second portion p2, an expansion effect is generated because the radial dimension of the third portion p3 is larger than that of the second portion p2. Therefore, an air pressure at the outlet 140a on the third portion p3 can be slightly smaller than the atmospheric pressure, i.e. the gas molecule density at the outlet 140a is lower, which is beneficial to the discharging to dissociate the working gas into plasma, and reduces the attenuation of the plasma.

Referring to FIG. 1 again, in some examples, the metal casing 110 further includes an air curtain device 190. The air curtain device 190 may be disposed at a bottom of the metal casing 110 and adjacent to the plasma jet 132. The air curtain device 190 can form an air curtain around the plasma jet 132. The air curtain can limit a range of the plasma, and can effectively prevent the plasma form damaging the non-treatment area. The air curtain device 190 may be an air extraction device or an air intake device.

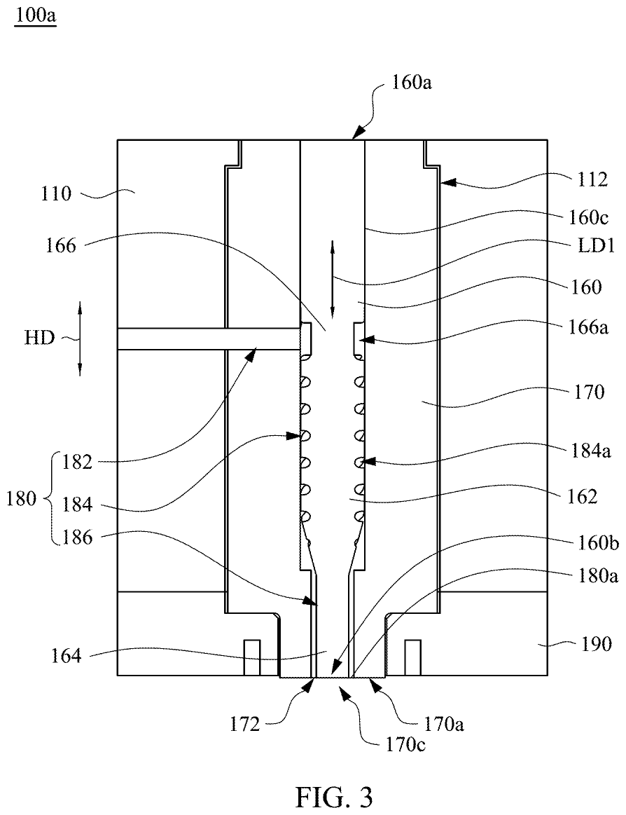

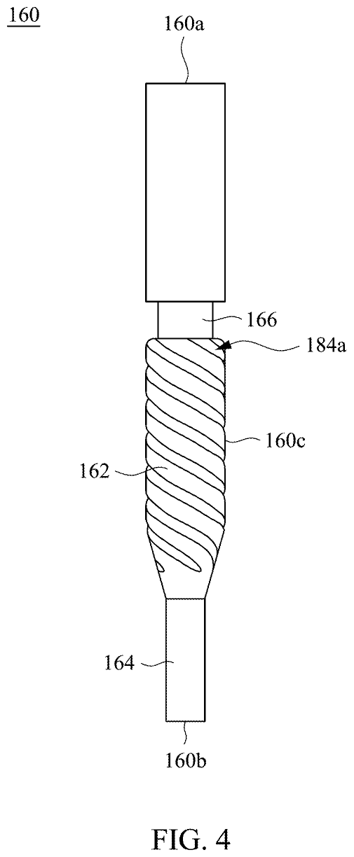

Referring to FIG. 3 and FIG. 4, FIG. 3 is a schematic cross-sectional view of a spot type atmospheric pressure plasma device in accordance with another embodiment of the present disclosure, and FIG. 4 is a schematic side view of a metal electrode of a spot type atmospheric pressure plasma device in accordance with another embodiment of the present disclosure. Similar to the structure of the aforementioned spot type atmospheric pressure plasma device 100, a spot type atmospheric pressure plasma device 100a mainly includes a metal casing 110, a metal electrode 160, a dielectric layer 170, and a gas channel 180. A difference between the spot type atmospheric pressure plasma devices 100a and 100 is that designs of the metal electrode 160 and the gas channel 180 are different from those of the metal electrode 120 and the gas channel 140. A structure of the dielectric layer 170 is modified according to the changes of the designs of the metal electrode 160 and the gas channel 180.

Similarly, the metal electrode 160 may be a long columnar structure. For example, the metal electrode 160 may be a cylindrical-like structure. The metal electrode 160 may be also disposed along a height direction HD of the metal casing 110, such that a length direction LD1 of the metal electrode 160 may be substantially parallel to the height direction HD of the metal casing 110. The metal electrode 160 has a top 160a and a bottom 160b, which are opposite to each other, and an outer side surface 160c connected between the top 160a and the bottom 160b. The top 160a of the metal electrode 160 is connected to the metal casing 110. A material of the metal electrode 160 may be any suitable metal, such as stainless steel, aluminum, and platinum.

The dielectric layer 170 is disposed within the inner space 112 of the metal casing 110 and surrounds the outer side surface 160c of the metal electrode 160. For example, the dielectric layer 170 may be a hollow columnar structure, and the metal electrode 160 is inserted in the dielectric layer 170. In the present embodiment, as shown in FIG. 3, the bottom 160b of the metal electrode 160 is in the bottom 170a of the dielectric layer 170, and there is a slit between the metal electrode 160 and the dielectric layer 170, such that a plasma jet 172 is formed in a central region 170c of the bottom 170a of the dielectric layer 170 around the periphery of the outer side surface 160c of the metal electrode 160. Therefore, the dielectric layer 170 does not cover the bottom 160b of the metal electrode 160. The dielectric layer 170 may be, for example, a circular tube structure, such as a quartz circular tube.

The gas channel 180 can guide the working gas from the outside of the spot type atmospheric pressure plasma device 100a to the plasma jet 172 of the dielectric layer 170 through the metal casing 110 and the dielectric layer 170. As shown in FIG. 3, similar to the aforementioned gas channel 140, the gas channel 180 includes a first section 182, a second section 184, and a third section 186, which are sequentially connected and in fluid communication with each other. The first section 182 may, for example, laterally pass through the metal casing 110 and the dielectric layer 170 from an outer side surface of the metal casing 110. The second section 184 extends between the dielectric layer 170 and the outer side surface 160c of the metal electrode 160. The second section 184 includes several spiral grooves 184a spirally arranged in the outer side surface 160c of the metal electrode 160, whereby the spiral groove 184a can guide the working gas to flow from the first section 182 to the third section 186 along the outer side surface 160c of the metal electrode 160. An outlet 180a of the gas channel 180 is located at an end of the third section 186.

In some examples, as shown in FIG. 3 and FIG. 4, the metal electrode 160 includes a first portion 162 and a second portion 164 connected to each other. The second section 184 of the gas channel 180 is between the first portion 162 and the dielectric layer 170, and the third section 186 is between the second portion 164 and the dielectric layer 170. In some exemplary examples, a radial dimension of the first portion 162 is greater than a radial dimension of the second portion 164, i.e. the second portion 164 is thinner than the first portion 162. The radial dimensions described here may be, for example, diameters.

By reducing the radial dimension of the second portion 164, which is adjacent to the plasma jet 172, the range of the working gas can be reduced, such that the plasma formed by the dissociation of the working gas can be more concentrated. Therefore, the spot type atmospheric pressure plasma device 100a can accurately and efficiently perform a plasma treatment on the workpiece.

In some examples, the metal electrode 160 further includes a third portion 166 connected to the first portion 162. Specifically, the third portion 166 and the second portion 164 are respectively connected to two opposite ends of the first portion 162. A radial dimension of the third portion 166 is smaller than the radial dimension of the first portion 162. As shown in FIG. 4, due to the radial dimension difference between the third portion 166 and the first portion 162, the third portion 166 may form an annular gas channel 166a. The annular gas channel 166a is in fluid communication with all the spiral grooves 184a, and the annular gas channel 166a is also in fluid communication with the first section 182 of the gas channel 180. The working gas flowing into the annular gas channel 166a from the first section 182 can flow into all the spiral grooves 184a almost simultaneously. Accordingly, the transmission efficiency of the working gas can be increased, and the uniformity of the gas distribution at the plasma jet 172 can be enhanced.

The gas channel 180 can guild and concentrate the working gas at the plasma jet 172, such that the plasma can be more focused, and most of the plasma can be formed closer to the workpiece to be processed. Therefore, the plasma energy can be confined to a smaller area, which can accurately and efficiently etch the material of the workpiece or remove the contamination on the workpiece.

According to the aforementioned embodiments, one advantage of the present disclosure is that a gas flow channel of a spot type atmospheric pressure plasma device of the present disclosure can directly guide a working gas to a plasma jet in a central area of a bottom of a dielectric layer. Accordingly, most of the working gas can be dissociated to form plasma near the plasma jet. Therefore, the formation of plasma in an inner space of a metal casing can be greatly reduced, which can not only avoid unnecessary waste of power, but also make the plasma more concentrated and closer to a workpiece to be processed, thereby enhancing a plasma treatment effect.

Another advantage of the present disclosure is that an outlet section of the gas flow channel of the spot type atmospheric pressure plasma device of the present disclosure may penetrate in a metal electrode, such that it can prevent plasma from being formed in the outlet section of the gas flow channel, further reduce unnecessary waste of power, and make the plasma more concentrated. Therefore, the plasma treatment can be more focused, thereby preventing a non-treatment area from being damaged.

Still another advantage of the present disclosure is that the spot type atmospheric pressure plasma device of the present disclosure may use a sealing ring to surround an outer side surface of the dielectric layer to seal a chamber of the metal casing, such that it can more effectively prevent plasma from being formed in the chamber.

Yet another advantage of the present disclosure is that the outlet section of the gas channel of the spot type atmospheric pressure plasma device of the present disclosure includes a reduction portion of a smaller radial dimension adjacent to the outlet. The gas can be compressed firstly in the reducing portion and then expanded at the outlet, such that the pressure at the outlet can be slightly lower than the atmospheric pressure, which is beneficial to the discharging to dissociate the working gas into plasma.

Further another advantage of the present disclosure is that the metal casing of the spot type atmospheric pressure plasma device of the present disclosure may include an air curtain device, and an air curtain may be formed on the periphery of the plasma jet to further limit the scope of the plasma, such that it can more effectively prevent the plasma from damaging the non-treatment area.

Although the present disclosure has been described in considerable detail with reference to certain embodiments thereof, the foregoing embodiments of the present disclosure are illustrative of the present disclosure rather than limiting of the present disclosure. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A spot type atmospheric pressure plasma device, comprising:
a metal casing, wherein the metal casing has an inner space;
a metal electrode disposed in the inner space;
a dielectric layer disposed in the inner space and surrounding an outer side surface of the metal electrode, wherein a central area of a bottom of the dielectric layer has a plasma jet, and a bottom of the metal electrode is adjacent to the plasma jet; and
a gas channel comprising:
a first section passing through the metal casing and the dielectric layer;
a second section connected to the first section and extending between the dielectric layer and the outer side surface of the metal electrode; and
a third section connected to the second section, and configured to direct a working gas to the plasma jet.

2. The spot type atmospheric pressure plasma device of claim 1, wherein the third section penetrates into the metal electrode from the outer side surface of the metal electrode, and extends from an interior of the metal electrode to the bottom of the metal electrode.

3. The spot type atmospheric pressure plasma device of claim 2, wherein the third section comprises:
a transverse portion laterally passing through the metal electrode; and
a longitudinal portion longitudinally extending from the transverse portion to the bottom of the metal electrode.

4. The spot type atmospheric pressure plasma device of claim 3, further comprising a sealing ring, wherein the metal electrode further comprises a groove disposed in the outer side surface of the metal electrode, the groove is located below the transverse portion, and the sealing ring is disposed in the groove and abuts against the dielectric layer.

5. The spot type atmospheric pressure plasma device of claim 2, wherein the third section includes a first portion, a second portion, and a third portion connected in sequence, an outlet of the gas channel is located in the third portion, and a radial dimension of the second portion is smaller than a radial dimension of the first portion and a radial dimension of the third portion.

6. The spot type atmospheric pressure plasma device of claim 1, wherein the second section comprises a plurality of spiral grooves spirally arranged in the outer side surface of the metal electrode to guide the working gas to the third section along the outer side surface of the metal electrode.

7. The spot type atmospheric pressure plasma device of claim 6, wherein the metal electrode comprises a first portion and a second portion connected to each other, the second section is located between the first portion and the dielectric layer, and the third section is located between the second portion and the dielectric layer, and wherein a radial dimension of the first portion is greater than a radial dimension of the second portion.

8. The spot type atmospheric pressure plasma device of claim 7, wherein the metal electrode further comprises a third portion connected to the first portion, and wherein a radial dimension of the third portion is smaller than the radial dimension of the first portion.

9. The spot type atmospheric pressure plasma device of claim 1, wherein the metal casing further comprises an air curtain device, and the air curtain device is adjacent to the plasma jet and is configured to form an air curtain around the plasma jet.

10. The spot type atmospheric pressure plasma device of claim 9, wherein the air curtain device is an air extraction device or an air intake device.
